(19) United States
(12) Patent Application Publication
(10) Pub. No.: US 2026/0002059 A1
(43) Pub. Date: Jan. 1, 2026

(54) ADHESIVE COMPOSITION, METHOD OF MANUFACTURING ADHESIVE LAYER, AND ELECTRONIC DEVICE

(71) Applicant: SAMSUNG DISPLAY CO., LTD., YONGIN-SI (KR)

(72) Inventors: HYUNJUNG LEE, Yongin-si (KR); WON-SEOK KIM, Yongin-si (KR); KANG-WOO LEE, Yongin-si (KR); Dasong LEE, Yongin-si (KR)

(21) Appl. No.: 19/171,430

(22) Filed: Apr. 7, 2025

(30) Foreign Application Priority Data
Jun. 26, 2024 (KR) 10-2024-0083514
Jul. 29, 2024 (KR) 10-2024-0100568

(51) Int. Cl. C09J 153/00; C08F 293/00; H05K 5/03

(52) U.S. Cl. CPC C09J 153/00; C08F 293/00; H05K 5/03; C08F 2810/20

(57) ABSTRACT

An adhesive composition includes a compound including a repeating unit derived from an acrylate monomer and an additive including a photoinitiator. As a terminal of the compound included in the adhesive composition is cured and a crosslinking structure is formed, volume change of a compound forming an adhesive layer is reduced, thereby preventing bubbles from penetrating into the adhesive layer from outside.

### CROSS-REFERENCE TO RELATED APPLICATIONS

This application claims priority under 35 USC § 119 to Korean Patent Application No. 10-2024-0083514, filed on Jun. 26, 2024 in the Korean Intellectual Property Office (KIPO) and Korean Patent Application No. 10-2024-0100568, filed on Jul. 29, 2024 in KIPO, the disclosures of which are incorporated by reference in their entireties herein.

### TECHNICAL FIELD

Embodiments of the present disclosure relate to an adhesive composition, a method of manufacturing an adhesive layer, a display device, and an electronic device.

### DISCUSSION OF RELATED ART

A display device includes a display panel that displays an image, a window that protects the display panel from external impact, scratches, or the like, and an adhesive layer that bonds the display panel and the window to each other. An optically clear adhesive (OCA) may be used as the adhesive layer. It is desired that the OCA has properties, such as excellent moisture resistance, heat resistance and adhesion, as well as high optical properties.

### SUMMARY

Embodiments of the present disclosure provide an adhesive composition with increased reliability.

Embodiments of the present disclosure provide a method of manufacturing an adhesive layer using the adhesive composition.

Embodiments of the present disclosure provide a display device manufactured using the adhesive composition.

Embodiments of the present disclosure provide an electronic device including the display device.

According to an embodiment of the present disclosure, an adhesive composition according to an embodiment of the present disclosure includes a compound including a repeating unit derived from an acrylate monomer, and an additive including a photoinitiator.

In an embodiment, the repeating unit may include a first sub-repeating unit and a second sub-repeating unit. The first and second sub-repeating units are derived from different acrylate monomers from each other.

In an embodiment, the first sub-repeating unit may be derived from an acrylate monomer including a hydroxyl group.

In an embodiment, the second sub-repeating unit may be derived from an acrylate monomer including an alkyl group.

In an embodiment, the compound may include a carbon-carbon double bond at at least one terminal.

In an embodiment, the compound may be formed from an intermediate compound including the repeating unit and a substituent at at least one terminal.

According to an embodiment of the present disclosure, a method of manufacturing an adhesive layer according to an embodiment of the present disclosure includes forming a first intermediate compound including a first repeating unit derived from an acrylate monomer, and forming a compound including the first repeating unit and a second repeating unit that forms a crosslinking structure at at least one terminal.

In an embodiment, the second repeating unit may include an alkyl group.

In an embodiment, the alkyl group may have 4n carbon atoms in which n is a natural number.

In an embodiment, the first repeating unit may include a first sub-repeating unit and a second sub-repeating unit are derived from different acrylate monomers from each other.

In an embodiment, the first sub-repeating unit may be derived from an acrylate monomer including a hydroxyl group.

In an embodiment, the second sub-repeating unit may be derived from an acrylate monomer including an alkyl group.

In an embodiment, the first intermediate compound may further include a carbon-carbon double bond at the at least one terminal, and the forming of the compound may include mixing the first intermediate compound and a first compound including an acrylate to form a compound precursor.

In an embodiment, the forming of the compound may further include curing the compound precursor.

In an embodiment, the forming of the first intermediate compound may include mixing a second intermediate compound including the first repeating unit and a substituent at at least one terminal and a second compound including an acrylate to form the first intermediate compound.

In an embodiment, in the forming of the compound, the crosslinking structure may be derived from a photoinitiator.

According to an embodiment of the present disclosure, a display device includes a display panel including a light emitting element, a window disposed on the display panel, and an adhesive layer disposed between the display panel and the window. The adhesive layer includes a compound including a first repeating unit derived from an acrylate monomer and a second repeating unit that forms a crosslinking structure at at least one terminal.

In an embodiment, the second repeating unit may include an alkyl group.

In an embodiment, the first repeating unit may include a first sub-repeating unit derived from an acrylate monomer including a hydroxyl group.

In an embodiment, the first repeating unit may further include a second sub-repeating unit derived from an acrylate monomer including an alkyl group.

According to an embodiment of the present disclosure, an electronic device may include a display device, and a power supply providing power to the display device. The display device may include a display panel including a light emitting element, a window disposed on the display panel, and an adhesive layer disposed between the display panel and the window. The adhesive layer includes a compound including a first repeating unit derived from an acrylate monomer and a second repeating unit that forms a crosslinking structure at at least one terminal.

According to an embodiment of the present disclosure, a display device includes a display panel including a light emitting element. A window is disposed on the display panel. An adhesive layer is disposed between the display panel and the window. The adhesive layer includes a compound represented by Formula 1;

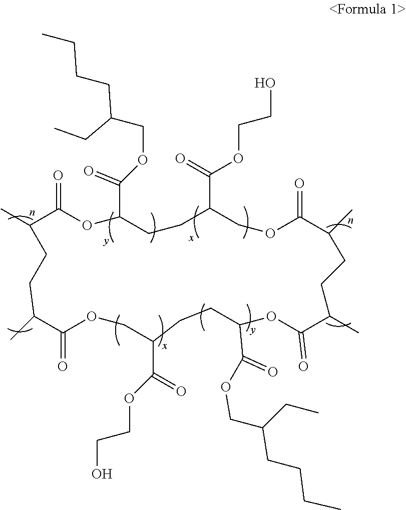

wherein in Formula 1, each of x, y, and n is a natural number.

In an embodiment, the compound is formed from a first intermediate compound represented by Formula 2:

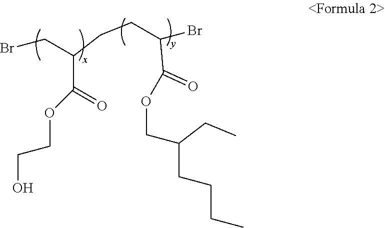

wherein in Formula 2, each of x and y is a natural number.

In an embodiment, the compound is formed by forming a second intermediate compound represented by Formula 3 from the first intermediate compound by adding a first compound including an acrylate to the first intermediate compound:

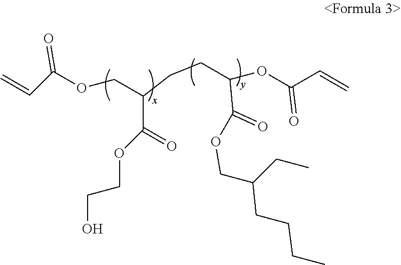

wherein in Formula 3, each of x and y is a natural number.

In an embodiment, the compound is formed by forming a compound precursor from the second intermediate compound by adding a second compound including an acrylate to the second intermediate compound and curing the compound precursor.

In an adhesive layer according to embodiments of the present disclosure, the adhesive layer may be formed from an adhesive composition including an intermediate compound including a repeating unit derived from an acrylate monomer and an additive including a photoinitiator. As a terminal of the intermediate compound included in the adhesive composition is cured to form a crosslinking structure, a volume change of a compound forming the adhesive layer is reduced, and thus bubbles may be prevented from penetrating into the adhesive layer from outside.

### BRIEF DESCRIPTION OF THE DRAWINGS

FIG. 1 is a plan view illustrating a display device according to an embodiment of the present disclosure.

FIG. 2 is a cross-sectional view illustrating the display device of FIG. 1 according to an embodiment of the present disclosure.

FIG. 3 is an example of a structural diagram schematically illustrating a compound included in an adhesive layer of FIG. 2 according to an embodiment of the present disclosure.

FIG. 4 is an example of a structural diagram schematically illustrating a compound included in an adhesive layer of FIG. 2 according to an embodiment of the present disclosure.

FIG. 5 is a cross-sectional view schematically illustrating a display panel included in the display device of FIG. 2 according to an embodiment of the present disclosure.

FIG. 6 is a block diagram illustrating an electronic device according to an embodiment of the disclosure according to an embodiment of the present disclosure.

FIG. 7 is a view illustrating an example in which the electronic device of FIG. 6 is implemented as a smart phone according to an embodiment of the present disclosure.

### DETAILED DESCRIPTION OF EMBODIMENTS

Hereinafter, embodiments of the present disclosure will be described in more detail with reference to the accompanying drawings. The same reference numerals are used for the same components in the drawings, and redundant descriptions of the same components may be omitted for economy of explanation.

A display device includes an adhesive composition in an adhesive layer securing a window to a display panel which prevents bubbles from penetrating into the adhesive layer from the external environment, such as during decompression in the manufacturing process of the display device when an autoclave process or the like is performed. Thus, a display device with increased reliability may be provided. The composition may include a first repeating unit including a first sub-repeating unit derived from an acrylate monomer including a hydroxyl group and a second sub-repeating unit derived from an acrylate monomer including an alkyl group.

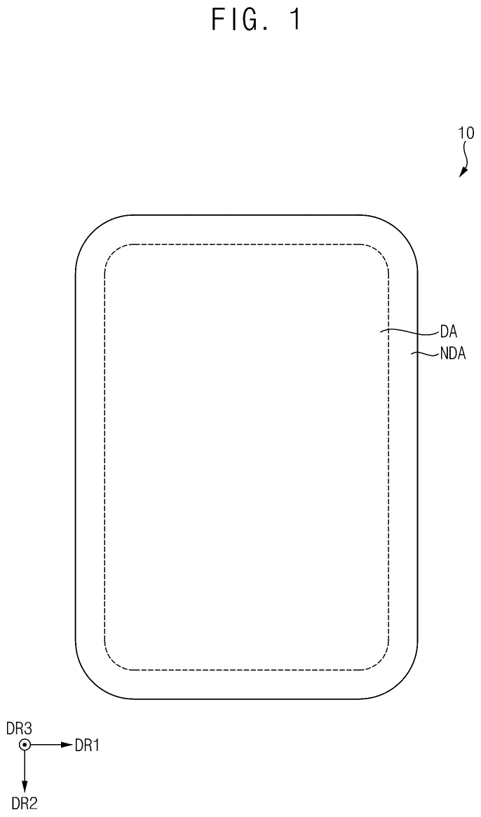

FIG. 1 is a plan view illustrating a display device according to an embodiment of the present disclosure.

Referring to FIG. 1, a display device 10 according to an embodiment of the present disclosure may include a display area DA and a non-display area NDA.

The display area DA may be an area that displays an image. In an embodiment, a plurality of pixels may be repeatedly disposed in the display area DA along a first direction DR1 and a second direction DR2 intersecting the first direction DR1 in a plan view. For example, in an embodiment the second direction DR2 may be perpendicular to the first direction DR1. However, embodiments of the present disclosure are not necessarily limited thereto and the first and second directions DR1, DR2 may cross each other at various different angles. Each of the pixels may be defined as a minimum light emitting unit that displays light.

Signal lines such as gate lines, data lines, or the like may be disposed in the display area DA. The signal lines may be connected to each of the pixels. Each of the pixels may receive gate signal, data voltage, or the like from the signal lines. Accordingly, an image may be displayed in the display area DA. For example, in an embodiment the image may be displayed in a third direction DR3 intersecting each of the first direction DR1 and the second direction DR2. For example, the third direction DR3 may be perpendicular to each of the first direction DR1 and the second direction DR2. However, embodiments of the present disclosure are not necessarily limited thereto.

The non-display area NDA may be an area that does not display an image. The non-display area NDA may be disposed around the display area DA (e.g., in the first and/or second directions DR1, DR2). For example, the non-display area NDA may surround the display area DA in a plan view. In some embodiments, the non-display area NDA may not be disposed on at least one side of the display area DA in a plan view. Drivers for displaying an image of the display area DA may be disposed in the non-display area NDA.

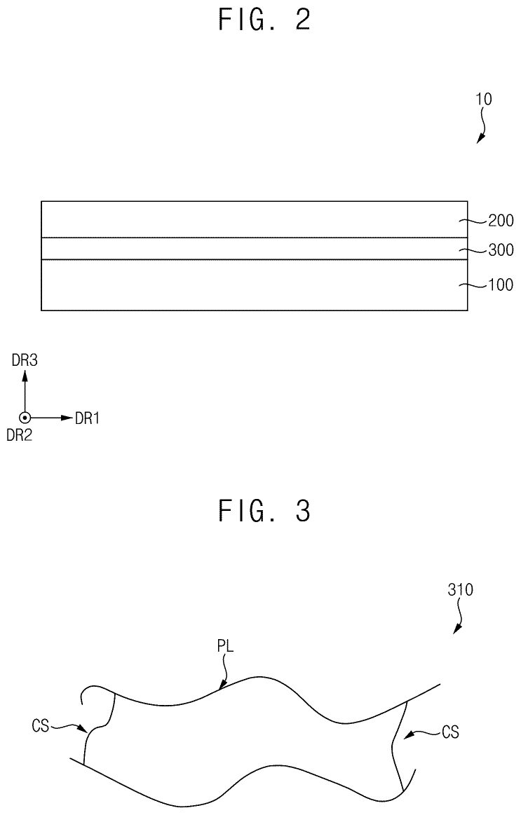

FIG. 2 is a cross-sectional view illustrating the display device of FIG. 1. FIG. 3 is an example of a structural diagram schematically illustrating a compound included in an adhesive layer of FIG. 2.

Referring to FIGS. 2 and 3, the display device 10 may include a display panel 100, a window 200, and an adhesive layer 300.

The display panel 100 may include the pixels and, accordingly, may display an image. The display panel 100 may emit light towards an upper surface (e.g., in the third direction DR3) to display the image.

The window 200 may be disposed on the display panel 100. The window 200 may cover the upper surface (e.g., a surface adjacent to the window 200 in a direction opposite to the third direction DR3) of the display panel 100. In an embodiment, the window 200 may include glass, plastic, or the like. The window 200 may block foreign substances penetrating from the outside (e.g., the external environment), and may prevent the display panel 100 from being damaged or malfunctioning due to an impact applied from the outside (e.g., the external environment). The window 200 may be optically transparent. Accordingly, the window 200 may transmit light emitted from the display panel 100.

In an embodiment, at least one functional coating layer may be further disposed between the display panel 100 and the window 200 (e.g., in the third direction DR3). The functional coating layer may be formed of a single layer or multiple layers. In an embodiment, the functional coating layer may include an optical coating layer that increases visibility of the display device 10, a primer coating layer that increases adhesion between the display panel 100 and the window 200, a high-strength coating layer that increases impact resistance of the display device 10, or the like.

The adhesive layer 300 (e.g., an adhesive composition) may be disposed between the display panel 100 and the window 200 (e.g., in the third direction DR3). The adhesive layer 300 may bond the display panel 100 and the window 200 to each other. For example, in an embodiment the adhesive layer 300 may include a pressure sensitive adhesive (PSA), an OCA, an optically clear resin (OCR), or the like. The adhesive layer 300 may include a compound 310.

In a manufacturing process of the display device 10, bubbles (e.g., air) may be generated (e.g., penetrated) from the outside (e.g., the external environment) into the adhesive layer 300. For example, in an autoclave process in which heat and pressure are applied to remove bubbles formed between the adhesive layer 300 and the window 200 during the manufacturing process of the display device 10, bubbles may be generated in the adhesive layer 300 during decompression. As the amount of the volume change of the compound 310 included in the adhesive layer 300 increases, an amount of bubbles penetrating may increase, so the compound 310 with a small volume change may be required.

Hereinafter, the compound 310 included in the adhesive layer 300 will be described in detail.

### <Compound>

Referring to FIG. 3, in an embodiment the compound 310 may include an acrylate-based resin that is derived from an acrylate monomer.

In an embodiment, the compound 310 may include a polymer chain PL and a crosslinking structure CS formed at a terminal. For example, the crosslinking structure CS may be formed at at least one terminal of the polymer chain PL. In an embodiment, the compound 310 may include a first repeating unit derived from an acrylate monomer and a second repeating unit that forms the crosslinking structure CS at the terminal.

In an embodiment, the first repeating unit may include a first sub-repeating unit and a second sub-repeating unit. The first sub-repeating unit and the second sub-repeating unit may be derived from different acrylate monomers from each other.

In an embodiment, the first sub-repeating unit may be a repeating unit derived from an acrylate monomer including a hydroxyl group. In this embodiment, the acrylate monomer may include a (meth)acrylate monomer.

For example, in an embodiment the (meth)acrylate monomer including a hydroxyl group may include hydroxyethyl (meth)acrylate, hydroxypropyl (meth)acrylate, hydroxybutyl (meth)acrylate, hydroxyhexyl (meth)acrylate, hydroxyoctyl (meth)acrylate, hydroxyethylene glycol (meth)acrylate, hydroxypropylene glycol (meth)acrylate, or the like. These compounds may be used alone or in combination with each other.

In an embodiment, the second sub-repeating unit may be a repeating unit derived from an acrylate monomer including an alkyl group. In this embodiment, the acrylate monomer may include a (meth)acrylate monomer.

For example, in an embodiment the (meth)acrylate monomer including an alkyl group may include methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethyl butyl (meth)acrylate, n-octyl (meth)acrylate, isooctyl (meth)acrylate, isononyl (meth)acrylate, or the like. These compounds may be used alone or in combination with each other.

In an embodiment, the second repeating unit may include an alkyl group. For example, the second repeating unit may include an alkyl group having 4n carbon atoms in which n is a natural number. In an embodiment, the polymer chains PL may be connected to each other through the crosslinking structure CS formed by the second repeating unit.

However, embodiments of the present disclosure are not necessarily limited thereto, and the monomer from which the first repeating unit is derived may be variously changed depending on physical properties of the compound 310, or the like. In addition, a content of each of the first and second repeating units in the compound 310 may be variously changed depending on the physical properties of the compound 310, or the like.

For example, in an embodiment the compound 310 may include a compound represented by following Formula 1.

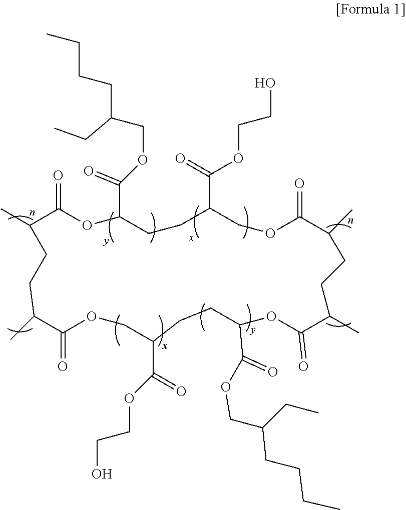

In the above Formula 1, each of x, y, and n may be a natural number that is adjusted depending on the physical properties of the compound, or the like.

### <Method of Manufacturing the Compound>

In an embodiment, the compound 310 may be manufactured by 1) polymerizing a monomer from which the first repeating unit is derived to form a first intermediate compound, 2) reacting the first intermediate compound with a first compound including an acrylate to replace a substituent at at least one terminal of the first intermediate compound with a carbon-carbon double bond to form a second intermediate compound, 3) mixing the second intermediate compound with a second compound including an acrylate to form a compound precursor, and 4) curing the compound precursor to form the crosslinking structure CS.

### 1) Formation of the First Intermediate Compound

In an embodiment, the first intermediate compound may be formed using a polymerization reaction. In this embodiment, various polymerization reactions such as solution polymerization, photopolymerization, bulk polymerization, suspension polymerization, or the like may be used as the polymerization reaction, and in particular, among them, a polymerization reaction that is easy to process and allows a polymer to be manufactured to have excellent uniformity may be used.

For example, in an embodiment the first intermediate compound may be formed by dissolving an acrylate monomer including a hydroxyl group from which the first sub-repeating unit is derived and an acrylate monomer including an alkyl group from which the second sub-repeating unit is derived in a solution and then polymerizing them.

In an embodiment, the first intermediate compound may include a substituent at at least one terminal. For example, in an embodiment the first intermediate compound may include a bromine (Br) substituent at the at least one terminal. However, embodiments of the present disclosure are not necessarily limited thereto. The first intermediate compound may have a structure including the substituent at the terminal and the first repeating unit at a side chain.

For example, in an embodiment the first intermediate compound may include a compound represented by following Formula 2.

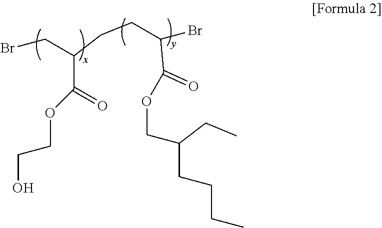

In the above Formula 2, each of x and y may be a natural number that is adjusted depending on the physical properties of the compound, or the like.

### 2) Formation of the Second Intermediate Compound

In an embodiment, after the polymerization reaction is performed, a first compound including an acrylate may be added to form the second intermediate compound. For example, in an embodiment the first compound may include sodium acrylate.

The second intermediate compound may be formed by substituting the substituent at the at least one terminal of the first intermediate compound with a portion of the first compound. For example, the second intermediate compound may be formed by substituting the substituent of the first intermediate compound with a carbon-carbon double bond of the first compound.

In an embodiment, the second intermediate compound may include a carbon-carbon double bond at at least one terminal. Accordingly, the at least one terminal of the second intermediate compound may be defined as a position at which a crosslinking reaction may occur. The second intermediate compound may have a structure including a carbon-carbon double bond at the at least one terminal and the first repeating unit at a side chain.

For example, the second intermediate compound may include a compound represented by following Formula 3.

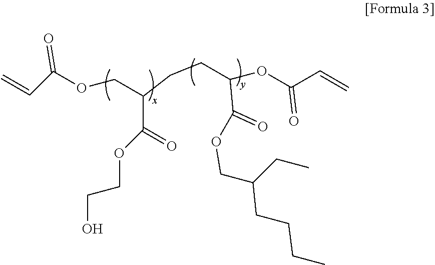

In the above Formula 3, each of x and y may be a natural number that is adjusted depending on the physical properties of the compound, or the like.

### 3) Formation of the Compound Precursor

Thereafter, in an embodiment, to form the compound precursor, the second intermediate compound, a second compound including acrylate, and a monomer may be mixed, and an additive may be added to the mixture. For example, in an embodiment the second compound may include polyacrylate or the like, the monomer may include an ultraviolet (UV) curable resin diluent or the like, and the additive may include a photoinitiator, a coupling agent, a curing agent, or the like.

In an embodiment, in addition to the above-described components, within a range that does not reduce the effects of embodiments of the present disclosure, a tertiary amine compound, a tackifier resin, a low molecular weight compound, an epoxy resin, an ultraviolet stabilizer, an antioxidant, a coloring agent, a reinforcing agent, an antifoaming agent, a surfactant, a foaming agent, an organic salt, a thickener, a flame retardant, or the like may be further added.

### 4) Formation of the Compound

Thereafter, in an embodiment, to form the compound 310, UV light may be irradiated on the compound precursor. A crosslinking reaction may occur in the compound precursor by the UV light irradiated on the compound precursor, and a crosslinking bond may be formed.

In an embodiment, the compound 310 may be formed by forming the second repeating unit that forms the crosslinking structure CS at at least one terminal of the compound precursor. In an embodiment, the compound 310 may be formed by forming the second repeating unit that forms the crosslinking structure CS at a position corresponding to the at least one terminal of the second intermediate compound.

In an embodiment, the compound 310 may include the crosslinking structure CS formed through the second repeating unit at the at least one terminal of the polymer chain PL. The polymer chains PL may be connected to each other through the crosslinking structure CS formed by the second repeating unit. The compound 310 may include the second repeating unit at the at least one terminal and the first repeating unit at a side chain.

A density of the crosslinking structure CS (e.g., a content of the second repeating unit) may be adjusted by an amount of UV light provided. For example, in an embodiment the density of the crosslinking structure CS may be increased by increasing the amount of UV light provided. For example, the density of the crosslinking structure CS may be adjusted depending on use, purpose, or the like of the compound 310.

In an embodiment, the crosslinking structure CS may be derived from a photoinitiator. For example, the crosslinking structure CS may not be derived from a crosslinking agent.

The photoinitiator may be a component that is excited by UV light or the like to initiate photopolymerization. For example, in an embodiment the photoinitiator may include Irgacure 184, Irgacure 369, Irgacure 651, Irgacure 819, Irgacure 907, benzione alkyl ether, benzophenone, benzyldimethyl ketal, hydroxycyclohexylphenyl acetone, chloroacetophenone, 1,1-dichloroacetophenone, diethoxyacetophenone, hydroxyacetophenone, 2-chlorothioxanthone, 2-ETAQ, 1-hydroxy-cyclohexyl-phenyl-ketone, 2-hydroxy-2-methyl-1-phenyl-1-propanone, methylbenzoyl formate, or the like. These compounds may be used alone or in combination.

When a content of the photoinitiator is less than a certain weight percentage (wt %), strength and adhesion of an adhesive may be reduced due to reduced curing or non-curing, and wrinkles may occur. In addition, when the content of the photoinitiator exceeds a certain wt %, contamination due to unreacted photoinitiator or reduced adhesion due to low polymerization degree may occur. For example, in an embodiment the photoinitiator may be Irgacure 651, and a content of the Irgacure 651 may be about 0.5 wt % based on a total weight of the compound precursor. However, embodiments of the present disclosure are not necessarily limited thereto.

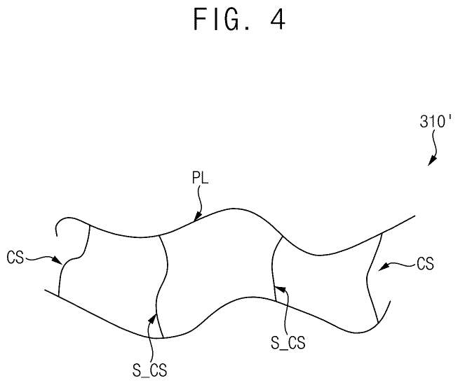

FIG. 4 is an example of a structural diagram schematically illustrating a compound included in an adhesive layer of FIG. 2.

A compound 310′ described with reference to FIG. 4 may be substantially the same as or similar to the compound 310 described with reference to FIG. 3, except for a sub-crosslinking structure S_CS. Hereinafter, redundant descriptions may be omitted or simplified for economy of explanation.

Referring to FIG. 4, the compound 310′ may include an acrylate-based resin.

In an embodiment, the compound 310′ may include a polymer chain PL having a crosslinking structure CS formed at at least one terminal and a sub-crosslinking structure S_CS formed at a side chain. The compound 310′ may include a first repeating unit that is derived from an acrylate monomer and forms the sub-crosslinking structure S_CS at the side chain and a second repeating unit that forms the crosslinking structure CS at the at least one terminal.

In an embodiment, the first repeating unit may include a first sub-repeating unit derived from an acrylate monomer including a hydroxyl group and a second sub-repeating unit derived from an acrylate monomer including an alkyl group.

In an embodiment, the second repeating unit may include an alkyl group. For example, the second repeating unit may include an alkyl group having 4n carbon atoms in which n is a natural number.

In an embodiment, the polymer chains PL may be connected to each other through the sub-crosslinking structure S_CS formed by the first repeating unit, and may also be connected to each other through the crosslinking structure CS formed by the second repeating unit. As a crosslinking bond is formed at the at least one terminal of the compound 310′ and a crosslinking bond is formed at the side chain of the compound 310′, a crosslinking density of the compound 310′ may be relatively increased as compared to an embodiment shown in FIG. 3, and modulus and impact resistance of the compound 310′ may be relatively increased.

In this embodiment, to form the compound 310′, a crosslinking agent may be additionally used. For example, in an embodiment, the crosslinking structure CS may be derived from a photoinitiator, and the sub-crosslinking structure S_CS may be derived from a crosslinking agent.

The adhesive layer 300 according to an embodiment of the present disclosure may include the compound 310 including the second repeating unit that forms the crosslinking structure CS at the at least one terminal. As the at least one terminal of the compound 310 forms the crosslinking structure CS, volume change of the compound 310 may be reduced. Accordingly, bubbles may be prevented from penetrating into the adhesive layer 300 from the outside (e.g., the external environment), such as during decompression in the manufacturing process of the display device when an autoclave process or the like is performed.

In addition, the adhesive layer 300 according to an embodiment of the present disclosure may include the compound 310′ including the first repeating unit that forms the sub-crosslinking structure S_CS at the side chain and the second repeating unit that forms the crosslinking structure CS at the at least one terminal. As the at least one terminal and the side chain of the compound 310′ form the crosslinking structures CS and S_CS, crosslinking density of the compound 310′ may be increased, and volume change of the compound 310′ may be reduced as compared to an embodiment shown in FIG. 3. Accordingly, bubbles may be prevented from penetrating into the adhesive layer 300 from the outside.

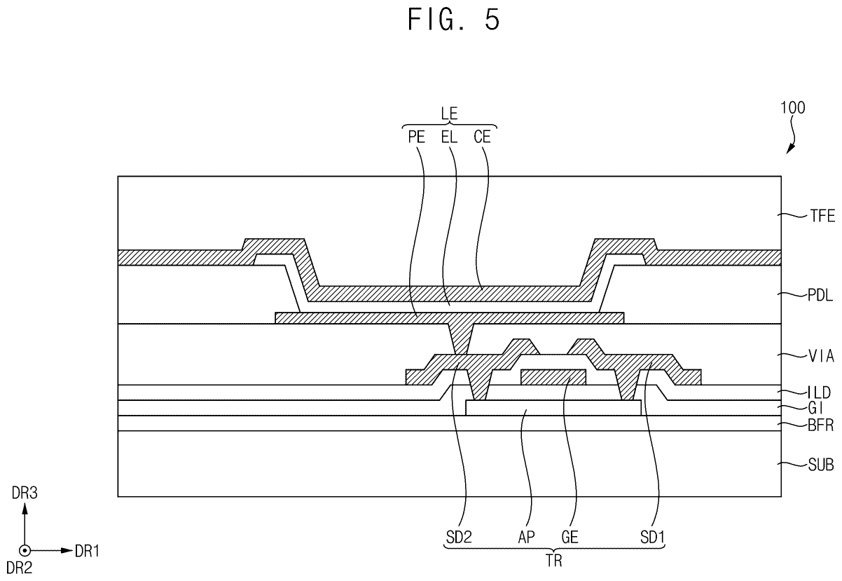

FIG. 5 is a cross-sectional view schematically illustrating a display panel included in the display device of FIG. 2.

Referring to FIG. 5, in an embodiment the display panel 100 may include a substrate SUB, a buffer layer BFR, a transistor TR, a gate insulating layer GI, an interlayer insulating layer ILD, a via insulating layer VIA, a light emitting element LE, a pixel defining layer PDL, and an encapsulation layer TFE. In an embodiment, the transistor TR may include an active pattern AP, a gate electrode GE, a first electrode SD1, and a second electrode SD2, and the light emitting element LE may include a pixel electrode PE, a light emitting layer EL, and a common electrode CE.

The substrate SUB may include a transparent material or an opaque material. For example, in an embodiment the substrate SUB may include glass, quartz, plastic, or the like. These materials may be used alone or in combination with each other.

The buffer layer BFR may be disposed on the substrate SUB (e.g., disposed directly thereon in the third direction DR3). The buffer layer BFR may prevent metal atoms, impurities, or the like from diffusing into the transistor TR. In an embodiment, the buffer layer BFR may include an inorganic material such as silicon oxide (SiOₓ), silicon nitride (SiNₓ), silicon oxynitride (SiOₓN_{y}), or the like. These materials may be used alone or in combination with each other.

The active pattern AP may be disposed on the buffer layer BFR (e.g., disposed directly thereon in the third direction DR3). The active pattern AP may include a source area, a drain area, and a channel area between the source area and the drain area. In an embodiment, the active pattern AP may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These materials may be used alone or in combination with each other.

The gate insulating layer GI may be disposed on (e.g., disposed directly thereon) the active pattern AP, and may cover the active pattern AP. In an embodiment, the gate insulating layer GI may include an inorganic material such as silicon oxide, silicon nitride, or silicon oxynitride. These materials may be used alone or in combination with each other.

The gate electrode GE may be disposed on the gate insulating layer GI (e.g., disposed directly thereon in the third direction DR3). The gate electrode GE may overlap the channel area of the active pattern AP in a plan view. In an embodiment, the gate electrode GE may include a metal, an alloy, a conductive metal oxide, a conductive metal nitride, a transparent conductive material, or the like. These materials may be used alone or in combination with each other.

The interlayer insulating layer ILD may be disposed on (e.g., disposed directly thereon) the gate electrode GE, and may cover the gate electrode GE. In an embodiment, the interlayer insulating layer ILD may include an inorganic material such as silicon oxide, silicon nitride, silicon oxynitride, or the like. These materials may be used alone or in combination with each other.

The first electrode SD1 and the second electrode SD2 may be disposed on the interlayer insulating layer ILD (e.g., disposed directly thereon in the third direction DR3). In an embodiment, the first electrode SD1 may be connected to (e.g., directly connected thereto) the source area of the active pattern AP through a first contact hole penetrating the gate insulating layer GI and the interlayer insulating layer ILD. The second electrode SD2 may be connected to (e.g., directly connected thereto) the drain area of the active pattern AP through a second contact hole penetrating the gate insulating layer GI and the interlayer insulating layer ILD. For example, in an embodiment each of the first electrode SD1 and the second electrode SD2 may include a metal, an alloy, a conductive metal oxide, a conductive metal nitride, a transparent conductive material, or the like. These materials may be used alone or in combination with each other.

Accordingly, the transistor TR including the active pattern AP, the gate electrode GE, the first electrode SD1, and the second electrode SD2 may be disposed on the substrate SUB.

The via insulating layer VIA may be disposed on (e.g., disposed directly thereon) the interlayer insulating layer ILD, and may cover the first and second electrodes SD1 and SD2. In an embodiment, the via insulating layer VIA may include an organic material such as phenol resin, acrylic resin, polyimide resin, polyamide resin, siloxane resin, epoxy resin, or the like. These materials may be used alone or in combination with each other.

The pixel electrode PE may be disposed on the via insulating layer VIA (e.g., disposed directly thereon in the third direction DR3). In an embodiment, the pixel electrode PE may be connected to (e.g., directly connected thereto) the second electrode SD2 through a contact hole penetrating the via insulating layer VIA. In an embodiment, the pixel electrode PE may include a metal, an alloy, a conductive metal nitride, a conductive metal oxide, a transparent conductive material, or the like. These materials may be used alone or in combination with each other. For example, the pixel electrode PE may operate as an anode.

The pixel defining layer PDL may be disposed on the via insulating layer VIA (e.g., disposed directly thereon in the third direction DR3), and may cover at least a portion of the pixel electrode PE. An opening exposing at least a portion of an upper surface of the pixel electrode PE may be defined in the pixel defining layer PDL. For example, the pixel defining layer PDL may cover ends of the pixel electrode PE and the opening may expose a central portion of the upper surface of the pixel electrode PE in some embodiments. The pixel defining layer PDL may include an inorganic material or an organic material. For example, in an embodiment the pixel defining layer PDL may include an organic material such as epoxy resin, siloxane resin, or the like. For another example, the pixel defining layer PDL may include an inorganic material or an organic material including a light blocking material having a black color.

The light emitting layer EL may be disposed on the pixel electrode PE (e.g., in the third direction DR3). The light emitting layer EL may be disposed on the pixel electrode PE exposed by the pixel defining layer PDL. The light emitting layer EL may include a material that emits light of a predetermined color.

The common electrode CE may be disposed on the light emitting layer EL (e.g., in the third direction DR3). In an embodiment, the common electrode CE may include a metal, an alloy, a conductive metal oxide, a conductive metal nitride, a transparent conductive material, or the like. These materials may be used alone or in combination with each other. For example, the common electrode CE may operate as a cathode.

Accordingly, the light emitting element LE including the pixel electrode PE, the light emitting layer EL, and the common electrode CE may be disposed on the substrate SUB. The light emitting element LE may be electrically connected to the transistor TR.

The encapsulation layer TFE may be disposed on the common electrode CE (e.g., disposed directly thereon in the third direction DR3). The encapsulation layer TFE may protect the light emitting element LE from external oxygen, moisture, or the like. The encapsulation layer TFE may include at least one inorganic layer and at least one organic layer.

Hereinafter, an embodiment is presented to help understand the present disclosure, but this is only for illustrative purposes, and the scope of the present disclosure is not necessarily limited to the following described embodiment.

### Synthesis of a First Intermediate Compound

1,4-bis(bromomethyl)benzene (1.0 eq), 2-hydroxyethyl acrylate (0.1 eq), copper bromide (1 eq), and copper(II) bromide (0.1 eq) are dissolved in acetone (0.1 M), and then argon gas is injected to degas for 20 minutes. 2,2′-bipyridine (2.0 eq) is added to the reaction mixture, and stirred at 50° C. for 1.5 hours to obtain a polymer. After removing catalyst and ligand from the polymer through a basic aluminum oxide column, the polymer is separated by precipitation using a solvent of methanol and distilled water in a ratio of 1:1. The precipitate is dried in an oven at 50° C. under reduced pressure at 8 mTorr for 24 hours to obtain a first intermediate compound.

### Synthesis of a Second Intermediate Compound

The first intermediate compound (1.0 eq) and sodium acrylate (6.0 eq) are dissolved in N,N-dimethylformamide (DMF) (0.3 M), and then stirred at room temperature for 24 hours. The reaction mixture is distilled under reduced pressure at 8 mbar to remove the DMF solvent, and extracted three times with dichloromethane (MC) and water to obtain an organic layer. The organic layer is distilled under reduced pressure to remove the MC solvent, and then separated through precipitation using a solvent of methanol and distilled water in a ratio of 1:1. The precipitate is dried in an oven at 50° C. under reduced pressure at 8 mTorr for 24 hours to obtain a second intermediate compound.

### Manufacturing of a Compound Precursor

100 parts by weight of the second intermediate compound, 70 parts by weight of polyacrylate, and 30 parts by weight of acryloyl morpholine are mixed, and then 0.5 wt % of Irgacure 651, 0.5 wt % of 3-methacryloxypropyltrimethoxysilane, and 1.0 wt % of toluene-2,4-diisocyanate are added to prepare a compound precursor.

### Manufacturing of a Compound

The compound precursor is bar-coated on a PET film (50 μm) as a base film, and is cured by irradiating with UV for 2 minutes.

### Evaluation

Adhesive layers of Examples 1 and 2 (e.g., the adhesive layer 300 of FIG. 2) are formed using the compound 310. In this case, the compound 310 includes the crosslinking structure CS at the terminal.

On the other hand, an adhesive layer of Comparative Example is formed using a compound including a crosslinking structure at a side chain. In this case, the compound does not include a crosslinking structure at a terminal.

For the adhesive layer 300 according to Examples 1 and 2 and the adhesive layer according to the Comparative Example, whether penetrating bubbles are generated (Y) or are not generated (N) after the autoclave process is measured.

TABLE 1

| | Bubble | Adhesion | Transmittance | Modulus |
|---|---|---|---|---|
| | generation | (gf) | (%) | (Mpa) |
| Example 1 | N | 1816 | 93 | 0.33 |
| Example 2 | N | 1800 | 93 | 0.36 |
| Comparative | Y | 1780 | 94 | 0.17 |
| Example | | | | |

Referring to Table 1, it is seen that bubble generation is prevented after the autoclave process in the adhesive layers 300 according to Examples 1 and 2. For example, it is seen that the adhesive layer 300 prevents bubble penetration from the outside (e.g., the external environment). In addition, it is seen that adhesion and transmittance of the adhesive layers 300 according to Examples 1 and 2 are excellent. On the other hand, it is seen that bubble generation is not prevented after the autoclave process in the adhesive layer according to Comparative Example. Accordingly, as the volume change of the compound 310 is suppressed through terminal crosslinking, the adhesive layer 300 with increased reliability with respect to bubble penetration may be provided.

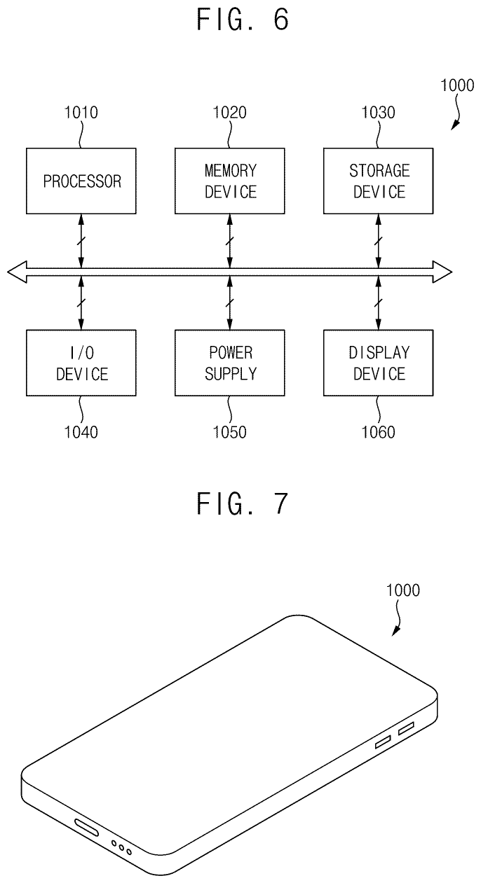

FIG. 6 is a block diagram illustrating an electronic device according to an embodiment of the disclosure. FIG. 7 is a view illustrating an example in which the electronic device of FIG. 6 is implemented as a smart phone.

Referring to FIGS. 6 and 7, in an embodiment the electronic device 1000 may include a processor 1010, a memory device 1020, a storage device 1030, an input/output (I/O) device 1040, a power supply 1050, and a display device 1060. The display device 1060 may be the display device 10 of FIG. 1. In addition, the electronic device 1000 may further include a plurality of ports for communicating with a video card, a sound card, a memory card, a universal serial bus (USB) device, other systems, or the like.

In an embodiment, as illustrated in FIG. 7, the electronic device 1000 may be implemented as a smart phone. However, the electronic device 1000 is not necessarily limited thereto. For example, the electronic device 1000 may be implemented as a cellular phone, a video phone, a smart pad, a smart watch, a tablet PC, a car navigation system, a computer monitor, a laptop, a head mounted display (HMD) device, or the like. However, embodiments of the present disclosure are not necessarily limited thereto and the electronic device 1000 that the display device 10 may be applied to may be various different small-sized, medium-sized or large-sized electronic devices.

The processor 1010 may perform various computing functions. The processor 1010 may be a microprocessor, a central processing unit (CPU), an application processor (AP), or the like. The processor 1010 may be coupled to other components through an address bus, a control bus, a data bus, or the like. In an embodiment, the processor 1010 may be coupled to an extended bus such as a peripheral component interconnection (PCI) bus.

The memory device 1020 may store data for operations of the electronic device 1000. For example, in an embodiment the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device 1030 may include a solid-state drive (SSD) device, a hard disk drive (HDD) device, a CD-ROM device, or the like. The I/O device 1040 may include an input device such as a keyboard, a keypad, a mouse device, a touch-pad, a touch-screen, or the like, and an output device such as a printer, a speaker, or the like. In an embodiment, the I/O device 1040 may include the display device 1060.

The I/O device 1040 may include an input device such as a keyboard, a keypad, a mouse device, a touch-pad, a touch-screen, and the like, and an output device such as a printer, a speaker, and the like. In an embodiment, the I/O device 1040 may include the display device 1060.

The power supply 1050 may provide power for operations of the electronic device 1000. The display device 1060 may be connected to other components through buses or other communication links.

Embodiments, of the present disclosure can be applied to various display devices and electric devices including the same. For example, embodiments of the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few non-limiting embodiments have been described, those skilled in the art will readily appreciate that many modifications are possible in the described embodiments without materially departing from the present disclosure. Accordingly, all such modifications are intended to be included within the scope of the present disclosure. Therefore, it is to be understood that the foregoing is illustrative of various embodiments and the present disclosure is not to be construed as limited to the described embodiments, and that modifications to the described embodiments, as well as other embodiments, are intended to be included within the scope of the present disclosure.

What is claimed is:

1. An adhesive composition comprising:
a compound including a repeating unit derived from an acrylate monomer; and
an additive including a photoinitiator.

2. The adhesive composition of claim 1, wherein the repeating unit includes a first sub-repeating unit and a second sub-repeating unit, the first and second sub-repeating units are derived from different acrylate monomers from each other.

3. The adhesive composition of claim 2, wherein:
the first sub-repeating unit is derived from an acrylate monomer including a hydroxyl group, and
the second sub-repeating unit is derived from an acrylate monomer including an alkyl group.

4. The adhesive composition of claim 1, wherein the compound includes a carbon-carbon double bond at at least one terminal.

5. The adhesive composition of claim 1, wherein the compound is formed from an intermediate compound including the repeating unit and a substituent at at least one terminal.

6. A method of manufacturing an adhesive layer, the method comprising:
forming a first intermediate compound including a first repeating unit derived from an acrylate monomer; and
forming a compound including the first repeating unit and a second repeating unit that forms a crosslinking structure at at least one terminal.

7. The method of claim 6, wherein the second repeating unit includes an alkyl group.

8. The method of claim 7, wherein the alkyl group has 4n carbon atoms, wherein n is a natural number.

9. The method of claim 6, wherein the first repeating unit includes a first sub-repeating unit and a second sub-repeating unit, the first and second sub-repeating units are derived from different acrylate monomers from each other.

10. The method of claim 9, wherein:
the first sub-repeating unit is derived from an acrylate monomer including a hydroxyl group, and
the second sub-repeating unit is derived from an acrylate monomer including an alkyl group.

11. The method of claim 6, wherein:
the first intermediate compound further includes a carbon-carbon double bond at the at least one terminal, and
the forming of the compound includes:
mixing the first intermediate compound and a first compound including an acrylate to form a compound precursor; and
curing the compound precursor.

12. The method of claim 6, wherein the forming of the first intermediate compound includes:
mixing a second intermediate compound including the first repeating unit and a substituent at at least one terminal and a second compound including an acrylate to form the first intermediate compound.

13. The method of claim 6, wherein in the forming of the compound, the crosslinking structure is derived from a photoinitiator.

14. An electronic device comprising:
a display panel including a light emitting element;
a window disposed on the display panel; and
an adhesive layer disposed between the display panel and the window, the adhesive layer including a compound including a first repeating unit derived from an acrylate monomer and a second repeating unit that forms a crosslinking structure at at least one terminal.

15. The electronic device of claim 14, wherein the second repeating unit includes an alkyl group.

16. The electronic device of claim 14, wherein the first repeating unit includes:
a first sub-repeating unit derived from an acrylate monomer including a hydroxyl group; and
a second sub-repeating unit derived from an acrylate monomer including an alkyl group.

17. The electronic device of claim 16, wherein the compound is represented by Formula 1; 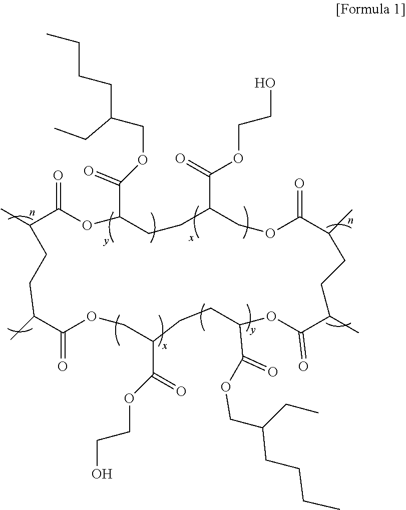
wherein in Formula 1, each of x, y, and n is a natural number.

18. The electronic device of claim 17, wherein the compound is formed from a first intermediate compound represented by Formula 2: 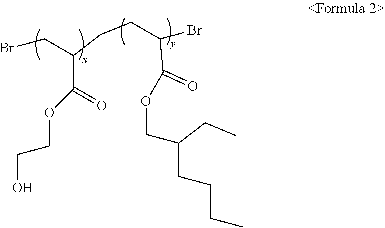
wherein in Formula 2, each of x and y is a natural number.

19. The electronic device of claim 18, wherein the compound is formed by forming a second intermediate compound represented by Formula 3 from the first intermediate compound by adding a first compound including an acrylate to the first intermediate compound: 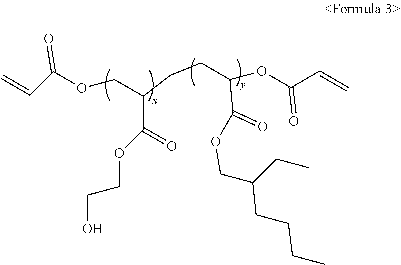
wherein in Formula 3, each of x and y is a natural number.

20. The electronic device of claim 19, wherein the compound is formed by forming a compound precursor from the second intermediate compound by adding a second compound including an acrylate to the second intermediate compound and curing the compound precursor.
